(19) United States
(12) Patent Application Publication
(10) Pub. No.: US 2009/0129020 A1
(43) Pub. Date: May 21, 2009

(54) ELECTRONIC APPARATUS

(75) Inventor: Nobuto Fujiwara, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/200,652

(22) Filed: Aug. 28, 2008

(30) Foreign Application Priority Data
Nov. 19, 2007 (JP) 2007-299852

(51) Int. Cl. H05K 7/20

(52) U.S. Cl. 361/697

(57) ABSTRACT

According to one embodiment, an electronic apparatus includes an heat producing component mounted on a first surface of a circuit board, a second heat producing component mounted on a second surface of the circuit board, a cooling fan overlapping the circuit board, a first heat radiating member located between the cooling fan and an exhaust aperture, a first heat transfer member which extends along the first surface of the circuit board and which transports heat generated by the first heat producing component to the first heat radiating member, a second heat radiating member including a part positioned opposite the second heat producing component with respect to the circuit board, and a second heat transfer member including a part extending along the second surface of the circuit board, the second heat transfer member transporting heat generated by the second heat producing component to the second heat radiating member.

### CROSS-REFERENCE TO RELATED APPLICATIONS

This application is based upon and claims the benefit of priority from Japanese Patent Application No. 2007-299852, filed Nov. 19, 2007, the entire contents of which are incorporated herein by reference.

### BACKGROUND

1. Field

One embodiment of the invention relates to an electronic apparatus equipped with a heat producing component.

2. Description of the Related Art

An electronic apparatus such as a portable computer is equipped with a heat producing component, for example, a CPU or a graphics chip. An example of a heat radiating structure that cools such a heat producing component is a remote heat exchanger (RHE). The basic configuration of the RHE includes heat radiating fins, a cooling fan that cools the heat radiating fins, and a heat pipe that transports heat generated by the heat producing component to the heat radiating fins.

Jpn. Pat. Appln. KOKAI Publication No. 10-107469 discloses an electronic apparatus comprising a cooling device that cools a plurality of heat producing components. The electronic apparatus comprises three heat producing components, three heat pipes, and a fin unit. Each of the three heat pipes are provided between a corresponding one of the heat producing components and the fin unit.

Jpn. UM Appln. KOKAI Publication No. 3-113893 discloses a cooling structure that cools heat producing members mounted on the front and back, respectively, of a board. The cooling structure has a plurality of cooling units each including heat radiating fins and a fan; the cooling units are installed for the respective individual heat producing members.

In the electronic apparatus described in the Jpn. Pat. Appln. KOKAI Publication No. 10-107469, the heat pipes are attached to the respective heat producing components arranged side by side in a horizontal direction. Thus, the plurality of heat pipes are arranged adjacent to one another in the horizontal direction. In such an electronic apparatus, the degree of freedom of arrangement of the heat pipes is limited. Thus, densely mounting the components of the electronic apparatus is difficult.

In the cooling structure described in Jpn. UM Appln. KOKAI Publication No. 3-113893, the cooling units are installed for the respective individual heat producing members mounted on the front and back of the board. Thus, the cooling structure becomes big.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary perspective view of the interior of the portable computer shown in FIG. 1;

FIG. 3 is an exemplary sectional view of the portable computer shown in FIG. 2, the view being taken along line F3-F3;

FIG. 4 is an exemplary perspective view of the interior of a portable computer according to a second embodiment of the present invention;

FIG. 5 is an exemplary perspective view of the interior of a portable computer according to a third embodiment of the present invention;

FIG. 6 is an exemplary sectional view of the portable computer shown in FIG. 5, the view being taken along line F6-F6;

FIG. 7 is an exemplary perspective view of the interior of a portable computer according to a fourth embodiment of the present invention;

FIG. 8 is an exemplary perspective view of the interior of a portable computer according to a fifth embodiment of the present invention;

FIG. 9 is an exemplary sectional view of the portable computer shown in FIG. 8, the view being taken along line F9-F9; and

FIG. 10 is an exemplary perspective view of the interior of a portable computer according to a sixth embodiment of the present invention.

### DETAILED DESCRIPTION

Various embodiments according to the invention will be described hereinafter with reference to the accompanying drawings. In general, according to one embodiment of the invention, an electronic apparatus comprises (i) a housing provided with an exhaust aperture, (ii) a circuit board contained in the housing and including a first surface and a second surface formed on a back of the first surface, (iii) a first heat producing component mounted on the first surface of the circuit board, (iv) a second heat producing component mounted on the second surface of the circuit board, (v) a cooling fan contained in the housing and overlapping the circuit board, the cooling fan being opposed to the first surface of the circuit board, (vi) a first heat radiating member located between the cooling fan and the exhaust aperture, (vii) a first heat transfer member which extends along the first surface of the circuit board and which transports heat generated by the first heat producing component to the first heat radiating member, (viii) a second heat radiating member located between the cooling fan and the exhaust aperture next to the first heat radiating member, (iX) the second heat radiating member including a part positioned opposite the second heat producing component with respect to the circuit board, and (x) a second heat transfer member including a part extending along the second surface of the circuit board, the second heat transfer member transporting heat generated by the second heat producing component to the second heat radiating member.

Embodiments of the present invention will be described below with reference to the drawings showing that the embodiments are applied to a portable computer.

### First Embodiment

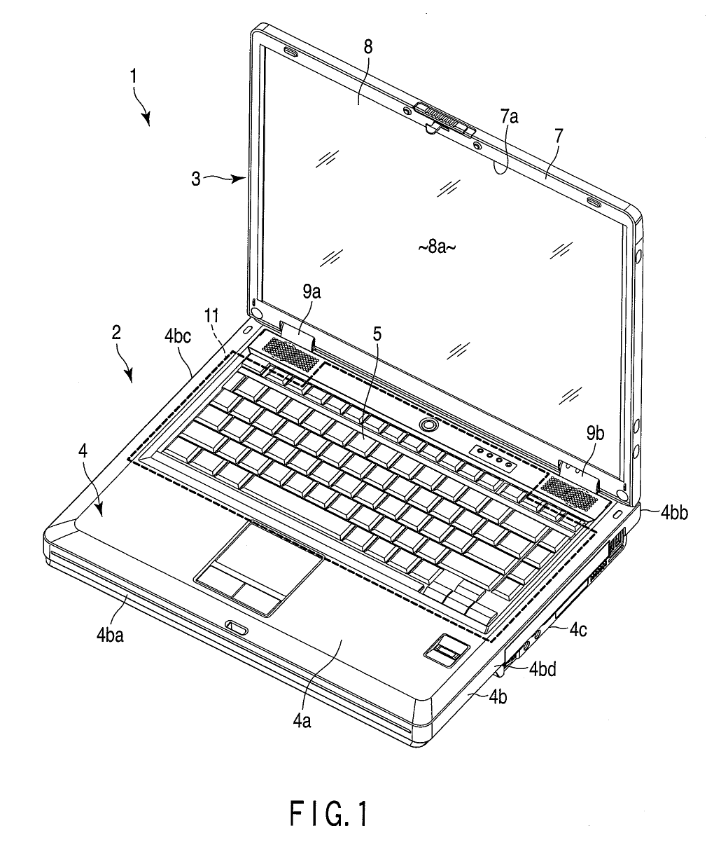

FIGS. 1 to 3 disclose a portable computer 1 as an electronic apparatus according to a first embodiment of the present invention. As shown in FIG. 1, the portable computer 1 comprises a main body 2 and a display unit 3.

The main body 2 has a housing 4 formed like a box. The housing 4 has a top wall 4a, a sidewall 4b, and a bottom wall 4c. The top wall 4a supports a keyboard 5. The sidewall 4b includes a front sidewall 4ba, a back sidewall 4bb, a right sidewall 4bc, and a left sidewall 4bd. The front sidewall 4ba is a wall part opposed to a user. The back sidewall 4bb is a wall part that faces in a direction opposite to the user.

The display unit 3 comprises a display housing 7 and a display device 8 contained in the display housing 7. The display device 8 has a display screen 8a. The display screen 8a is exposed to the exterior of the display housing 7 through an opening 7a in a front surface of the display housing 7.

The display unit 3 is supported at a back end part of the housing 4 via a pair of hinge parts 9a, 9b. Thus, the display unit 3 is rotatable between a closed position where the display unit 3 is brought down so as to cover the top wall 4a from above and an open position where the display unit 3 is raised upright so as to expose the top wall 4a.

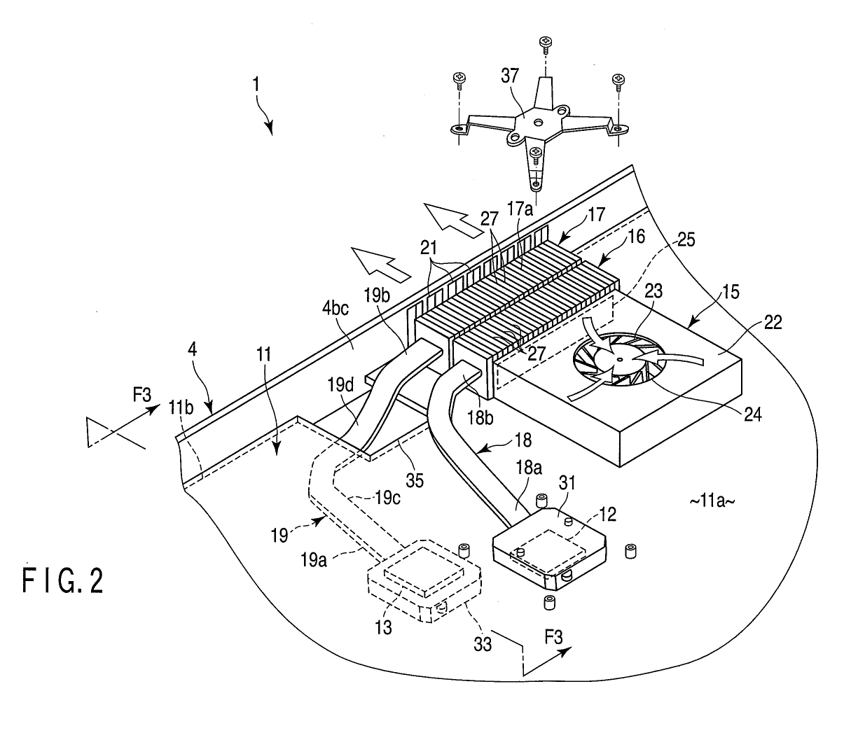

As shown in FIG. 1, a circuit board 11 is contained in the housing 4. As shown in FIG. 2, a plurality of heat producing components 12, 13 are mounted on the circuit board 11. The heat producing components 12, 13 are electronic components that generate heat during use. Specific examples of the heat producing components 12, 13 include a CPU, a graphics chip, North Bridge (trade mark), and a memory. However, the heat producing components 12, 13 are not limited to these examples and may be various components that are desired to radiate heat.

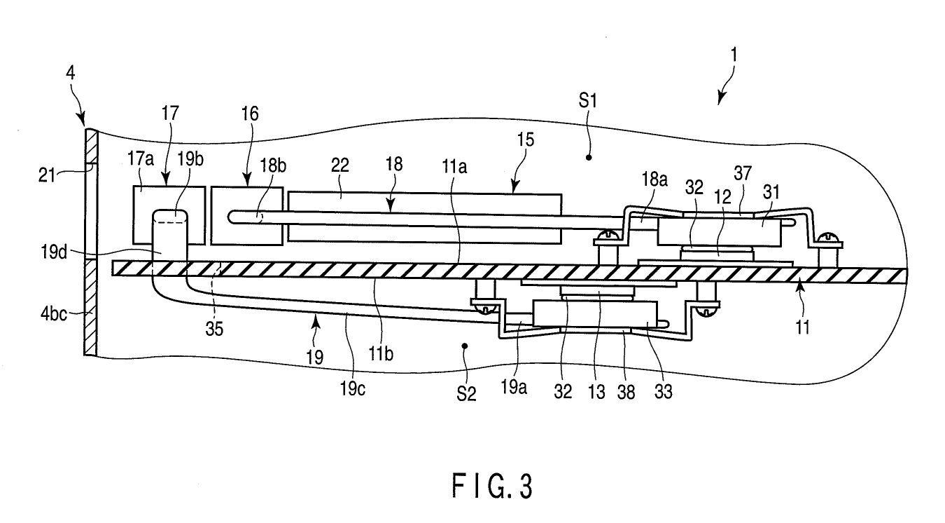

As shown in FIGS. 2 and 3, the circuit board 11 has a first surface 11a and a second surface 11b formed on the back of the first surface 11a. In the present embodiment, the first surface 11a is a top surface of the circuit board 11 and is opposed to the top wall 4a. On the other hand, the second surface 11b is a bottom surface of the circuit board 11 and is opposed to the bottom wall 4c. The present invention is not limited to this aspect. The first surface 11a may be a bottom surface, and the second surface 11b may be a top surface.

As shown in FIGS. 2 and 3, the plurality of heat producing components 12, 13 are separately mounted on the top and bottom surfaces of the circuit board 11. Specifically, the first heat producing component 12 is mounted on the first surface 11a of the circuit board 11. The second heat producing component 13 is mounted on the second surface 11b of the circuit board 11. A heat radiating structure that cools the first and second heat producing components 12, 13 will be described below as an example of the present invention. The present invention is not limited to this aspect but is applicable to a heat radiating structure that cools at least three heat producing components.

As shown in FIG. 2, the housing 4 contains a cooling fan 15, a first heat radiating member 16 and a second heat radiating member 17, and a first heat pipe 18 and a second heat pipe 19. The cooling fan 15 is located in the vicinity of the right sidewall 4bc in the housing 4. Here, the circuit board 11 is provided with no cutout corresponding to the cooling fan 15. The cooling fan 15 is positioned on the circuit board 11.

Specifically, as shown in FIG. 3, the cooling fan 15 overlaps the circuit board 11 and opposed to the first surface 11a. That is, in the present embodiment, the cooling fan 15 is provided in an area S1 above the circuit board 11. The present invention is not limited to this aspect. The cooling fan 15 may be provided in an area S2 below the circuit board 11.

As shown in FIG. 2, the right sidewall 4bc of the housing 4, opposed to the cooling fan 15, is provided with, for example, a plurality of exhaust apertures 21. The exhaust apertures 21 are open to the exterior of the housing 4. The cooling fan 15 has a fan case 22, and an impeller 23 (i.e., a fan blade) that is rotationally driven in the fan case 22. The fan case 22 is provided with an air inlet 24 through which air is drawn and an air outlet 25 through which the drawn air is discharged.

The air inlet 24 is provided on, for example, each of a top surface and a bottom surface of the cooling fan 15. The air outlet 25 is provided on a side surface of the cooling fan 15 and opposed to the exhaust apertures 21 in the housing 4. The cooling fan 15 discharges air from the air outlet 25 toward the exhaust apertures 21. Here, the first and second heat producing components 12 and 13 are arranged, for example, closer to the front sidewall 4ba of the portable computer, that is, a wall part corresponding to the user side, than the cooling fan 15.

As shown in FIG. 2, the first and second heat radiating members 16, 17 are arranged, for example, in the vicinity of the right sidewall 4bc of the housing 4. The first and second heat radiating members 16, 17 are arranged side by side in a direction in which the cooling fan 15 discharges air. The first and second heat radiating members 16, 17 are also located between the air outlet 25 in the cooling fan 15 and the exhaust apertures 21 in the housing 4. The first and second heat radiating members 16, 17 extend parallel to each other in a direction that traverses the air discharge direction of the cooling fan 15.

More specifically, the first heat radiating member 16 is provided adjacent to the cooling fan 15. The second heat radiating member 17 is provided so as to sandwich the first heat radiating member 16 between the second heat radiating member 17 and the cooling fan 15. As shown in FIGS. 2 and 3, in the present embodiment, the first and second heat radiating member 16, 17 overlap the circuit board 11. In other words, the circuit board 11 is provided in an area in which the circuit board 11 overlaps the first heat radiating member 16 and in an area in which the circuit board 11 overlaps the second heat radiating member 17.

In the present embodiment, the first and second heat radiating members 16, 17 overlap the circuit board 11 in the same direction in which the cooling fan 15 overlaps the circuit board 11. That is, the first and second heat radiating members 16, 17 are provided in the area S1 above the circuit board 11 and opposed to the first surface 11a.

Namely, the second heat radiating member 17 includes a part 17a positioned opposite the second heat producing component 13 with respect to the circuit board 11. The expression “include a part positioned opposite the second heat producing component with respect to the circuit board” includes a case where the entire second heat radiating member 17 is positioned opposite the second heat producing component 13 with respect to the circuit board 11.

Each of the first and second heat radiating members 16, 17 is a fin unit formed of an assembly of a plurality of fins 27. Each of the fins 27 is a plate-like member formed, for example, like a rectangle and having an upper end and a lower end both of which are folded in a horizontal direction. The fin 27 is formed of metal having a high heat conductivity, for example, aluminum. The plurality of fins 27 are provided at intervals so that plate surfaces of the fins 27 extend along the flow direction of air from the cooling fan 15.

The first heat pipe 18 is an example of a first heat transfer member that transports heat generated by the first heat producing component 12 to the first heat radiating member 16. The second heat pipe 19 is an example of a second heat transfer member that transports heat generated by the second heat producing component 13 to the second heat radiating member 17. Each of the first and second heat pipes 18, 19 internally has an operating fluid to move heat between a heat receiving end part and a heat radiating end part utilizing the heat of evaporation and capillary action.

As shown in FIGS. 2 and 3, a first heat receiving member 31 is thermally connected to the first heat producing component 12. The first heat receiving member 31 is formed of, for example, metal and has a high heat conductivity. A heat connecting member 32, for example, heat transfer grease or a heat transfer sheet, is interposed between the first heat producing component 12 and the first heat receiving member 31.

The first heat pipe 18 has a first end part 18a as a heat receiving end part and a second end part 18b as a heat radiating end part. The first end part 18a of the first heat pipe 18 is connected to the first heat receiving member 31. As shown in FIGS. 2 and 3, the first heat pipe 18 extends along the first surface 11a of the circuit board 11. The second end 18b of the first heat pipe 18 is connected to the first heat radiating member 16 in an area positioned on the same side of the circuit board 11 on which the first heat producing component 12 is positioned. In the present embodiment, the area positioned on the same side of the circuit board 11 on which the first heat producing component 12 is positioned refers to the area S1 above the circuit board 1.

As shown in FIGS. 2 and 3, the second heat receiving member 33 is thermally connected to the second heat producing component 13. The second heat receiving member 33 is formed of, for example, metal and has a high heat conductivity. The heat connecting member 32 is interposed between the second heat producing component 13 and the second heat receiving member 33.

The second heat pipe 19 has a first end part 19a as a heat receiving end part and a second end part 19b as a heat radiating end part. The first end part 19a of the second heat pipe 19 is connected to the second heat receiving member 33. As shown in FIGS. 2 and 3, the second heat pipe 19 includes a part 19c extending along the second surface 11b of the circuit board 11.

The second heat pipe 19 further includes a part 19d extending, while inclining in a thickness direction of the circuit board 11, from an area positioned on the same side of the circuit board 11 on which the second heat producing component 13 is positioned to an area positioned opposite the second heat producing component 13 with respect to the circuit board 11. In the present embodiment, the area positioned on the same side of the circuit board 11 on which the second heat producing component 13 is positioned refers to the area S2 below the circuit board 11. In the present embodiment, the area positioned opposite the second heat producing component 13 with respect to the circuit board 11 refers to the area S1 above the circuit board 11.

Specifically, a cutout 35 is formed in a portion of a peripheral part of the circuit board 11 which overlaps the second heat pipe 19. The second heat pipe 19 extends through the cutout 35 to the area S1 above the circuit board 11. The second end part 19b of the second heat pipe 19 is connected to the second heat radiating member 17 in the area S1 above the circuit board 11 (i.e., in the area positioned opposite the second heat producing component 13 with respect to the circuit board 11).

Here, the first and second heat pipes 18, 19, extend to the cooling fan 15 from the same side of the cooling fan 15. Specifically, the first and second pipes 18, 19 extend through between the cooling fan 15 and the front sidewall 4ba of the housing 4 to an area located opposite the air outlet 25 in the cooling fan 15.

As shown in FIG. 3, the portable computer 1 comprises a first pressing member 37 and a second pressing member 38 each of which is a leaf spring. The first pressing member 37 presses the first heat receiving member 31 toward the first heat producing component 12. The second pressing member 38 presses the second heat receiving member 33 toward the second heat producing component 13.

Now, the operation of the portable computer 1 will be described.

The use of the portable computer 1 causes the first and second heat producing components 12, 13 to generate heat. Most of the heat generated by the first heat producing component 12 is transported to the first heat radiating member 16 by the first heat pipe 18. Most of the heat generated by the second heat producing component 13 is transported to the second heat radiating member 17 by the second heat pipe 19.

Driving the cooling fan 15 allows air to be discharged through the air outlet 25 to forcibly cool the first and second heat radiating members 16, 17. The heat moved from the heat producing components 12, 13 to the first and second heat radiating members 16, 17 is taken by the air discharged from the cooling fan 15 and discharged to the exterior of the housing 4 through the exhaust apertures 21. This promotes cooling of the first and second heat producing components 12, 13.

The portable computer 1 configured as described above can ensure a large board area and allow the components to be densely mounted in the computer 1. That is, the heat pipes 18, 19 are thermally connected to respective heat producing components 12, 13, separately mounted on the first and second surfaces 11a, 11b of the circuit board 11. The heat radiating members 16, 17 to which the heat pipes 18, 19 are connected, are brought together in one area and cooled by the single cooling fan 15. Thus, the cooling structure that promotes cooling of the plurality of heat producing components 12, 13 have a relatively small size.

Namely, since the plurality of heat producing components 12, 13 are separately mounted on the first and second surfaces 11a, 11b of the circuit board 11, the first heat pipe 18 and the second heat pipe 19 are prevented from lying adjacent to each other on one surface of the circuit board 11. That is, the degree of freedom of the arrangement of the first and second heat pipes 18, 19 is unlikely to be limited. For example, the heat pipes 18, 19 may be shortened. This enables the components of the electronic apparatus to be densely mounted.

For example, with a reduction in the need to take into account a space required for arrangement of the heat pipes 18, 19, the first and second heat producing components 12, 13, arranged on the top and bottom surfaces, respectively, of the circuit board 11, can be located closer to each other. That is, the plurality of heat producing components 12, 13 can be densely mounted.

Furthermore, components with relatively high mounting heights are difficult to mount in areas of the circuit board which overlap the heat pipes. Thus, if the plurality of heat pipes extend over one surface of the circuit board 11, the degree of freedom of mounting on this surface of the circuit board 11 is significantly limited. On the other hand, when the plurality of heat pipes 18, 19 are separately provided on the opposite surfaces of the circuit board 11, the degree of freedom of mounting on one surface of the circuit board 11 can be prevented from being significantly limited.

The configuration with the cooling fan 15 overlapping the circuit board 11 can ensure the increased board area of the circuit board 11 compared to a configuration provided with a cutout corresponding to the external shape of the cooling fan 15. The capability of increasing the board area of the circuit board 11 can improve the flexibility of board design. This may contribute to allowing the components of the electronic apparatus to be densely mounted.

For example, if the plurality of heat pipes extend to the cooling fan from the opposite sides of the cooling fan, respectively, when the user tilts the portable computer during use, either of the heat pipes may be in a top heat condition.

On the other hand, the first and second heat pipes 18, 19 can be arranged to extend to the cooling fan 15 from the same side of the cooling fan 15, the layout of the apparatus can be designed such that the plurality of heat pipes 18, 19 are likely to be in a bottom heat condition.

For example, some users tilt the portable computer 1 so that the back of the computer 1 is higher than the front of the computer 1 so as to tilt the keyboard 5 such that the back of the keyboard 5 is higher than the front of the keyboard 5 (such that the height of the keyboard 5 increases as the keyboard 5 extends away from the user). When the keyboard 5 is tilted such that the back of the keyboard 5 is higher than the front of the keyboard 5, the bottom heat condition is established in which the heat receiving end parts 18a, 19a of the first and second heat pipes 18, 19 are located below, whereas the heat radiating end parts 18b, 19b of the first and second heat pipes 18, 19 are located above.

In the case where the second heat pipe 19 extends, while inclining in the thickness direction of the circuit board 11, from the area positioned on the same side of the circuit board 11 on which the second heat producing component 13 is positioned to the area positioned opposite the second heat producing component 13 with respect to the circuit board 11, a high heat transmission efficiency can be maintained between the second heat producing component 13 and second heat radiating member 17, which are arranged opposite each other with respect to the circuit board 11.

In particular, in the case where the second heat radiating member 17 is located in the area S1 above the circuit board 11 and the second heat pipe 19 extends from the area S2 below the circuit board 11 to the area S1 above the circuit board 11, the second heat pipe 19 is likely to be in the bottom heat condition. This can allow heat to be appropriately transported.

In the case where the first heat radiating member 16 overlaps the circuit board in the same direction in which the cooling fan 15 overlaps the circuit board 11, no cutout corresponding to the first heat radiating member 16 needs to be formed. A large board area can thus be ensured for the circuit board 11. In the case where the second heat radiating member 17 overlaps the circuit board in the same direction in which the cooling fan 15 overlaps the circuit board 11, no cutout corresponding to the second heat radiating member 17 needs to be formed. A large board area can thus be ensured for the circuit board 11.

The configuration including the cutout 35 formed in the circuit board 11 and through which the second heat pipe 19 passes enables a reduction in the length of the second heat pipe 19 and an increase in the size of the circuit board 11 compared to, for example, a configuration with the second heat pipe bypassing an edge of the circuit board 11.

In the above-described embodiment, the first heat radiating member 16 corresponding to the first heat producing component 12, is provided adjacent to the cooling fan 15. However, the present invention is not limited to this aspect. The second heat radiating member 17, corresponding to the second heat producing component 13, located opposite the first heat producing component 12 with respect to the circuit board 11, may be provided adjacent to the cooling fan 15.

If for example, two heat producing components are mounted in the electronic apparatus, either of the heat producing components may be the first heat producing component 12. For example, if one of the heat producing components involves a larger power consumption than the other, the cooling performance of the entire electronic apparatus can be improved by designing the heat radiating structure such that the heat producing component with the larger power consumption is thermally connected to the shorter heat transfer member, that is, the shorter one of the first and second heat pipes 18, 19.

Furthermore, in an electronic apparatus expected to be often tilted during use, the second heat pump 19, which is likely to be in the bottom heat condition, allows heat to be transported more stably than the first heat pipe 18. Consequently, the cooling performance of the entire electronic apparatus is likely to be stabilized by thermally connecting the heat producing component with the larger power consumption to the second heat pipe 19.

### Second Embodiment

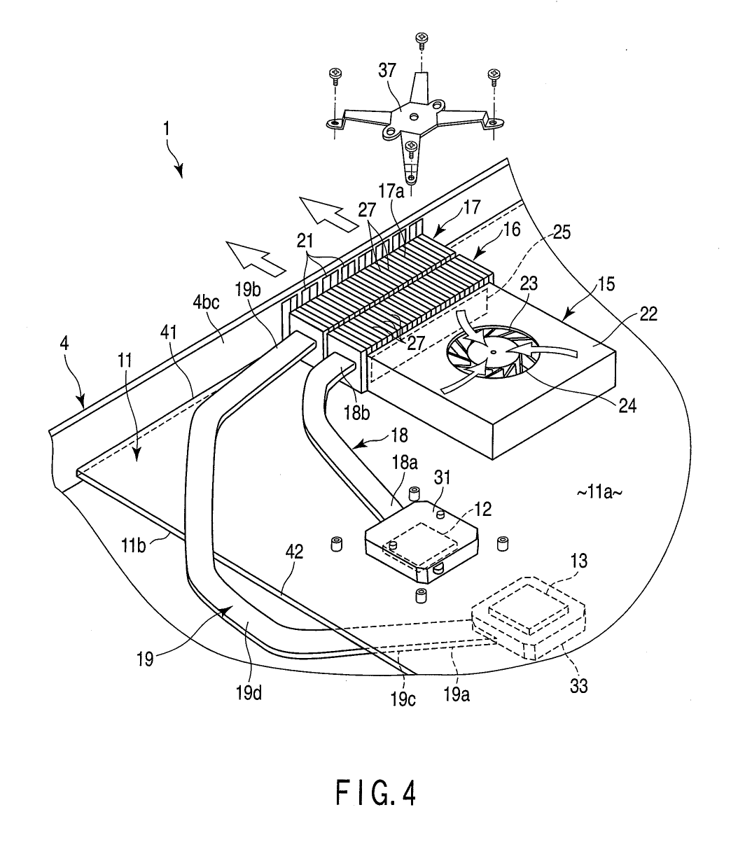

Now, the portable computer 1 as an electronic apparatus according to a second embodiment of the present invention will be described with reference to FIG. 4. Configurations of the second embodiment providing the same functions as or functions similar to those of the corresponding configurations of the first embodiment are denoted by the same reference numbers and will not be described below.

The circuit board 11 according to the present embodiment is provided with no cutout through which the second heat pipe 19 passes. The second heat pipe 19 extends so as to bypass the periphery of the circuit board 11. Specifically, the circuit board 11 has a first edge portion 41 opposed to the right sidewall 4bc, in which the exhaust apertures 21 are formed, and a second edge portion 42 located adjacent to the first edge portion 41 and opposite, for example, the front sidewall 4ba.

The second heat pump 19 extends to an area located off from the circuit board 11 and then inclines, in the area located off from the circuit board 11, toward an area positioned opposite the second heat producing component 13 with respect to the circuit board 11. Thus, the second heat pipe 19 extends from the lower side to upper side of the circuit board 11 across the second edge portion 42 of the circuit board 11. The remaining configurations of the portable computer 1 of the second embodiment are the same as those of the first embodiment.

The portable computer 1 configured as described above can ensure a large board area and allow the components to be densely mounted as is the case with the first embodiment.

### Third Embodiment

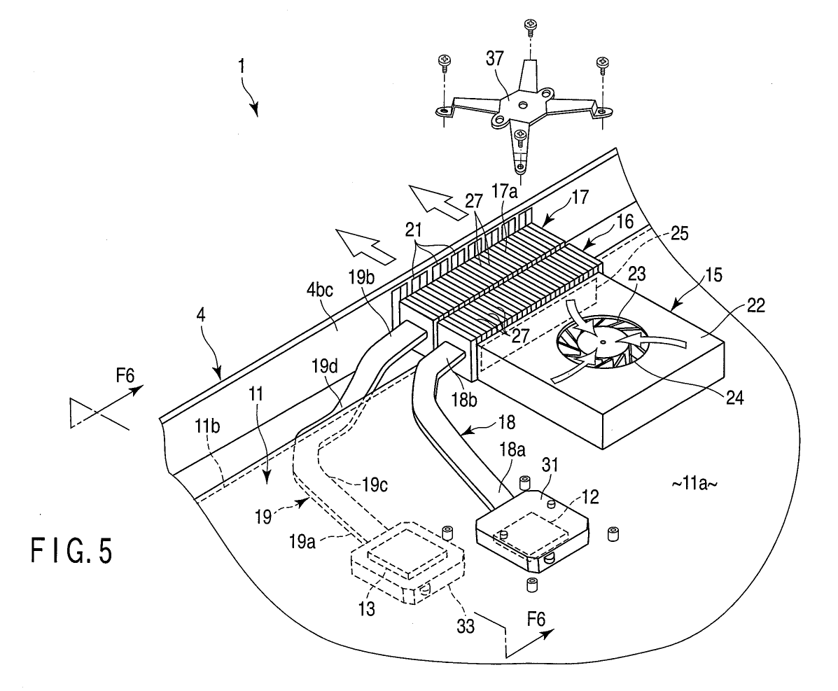

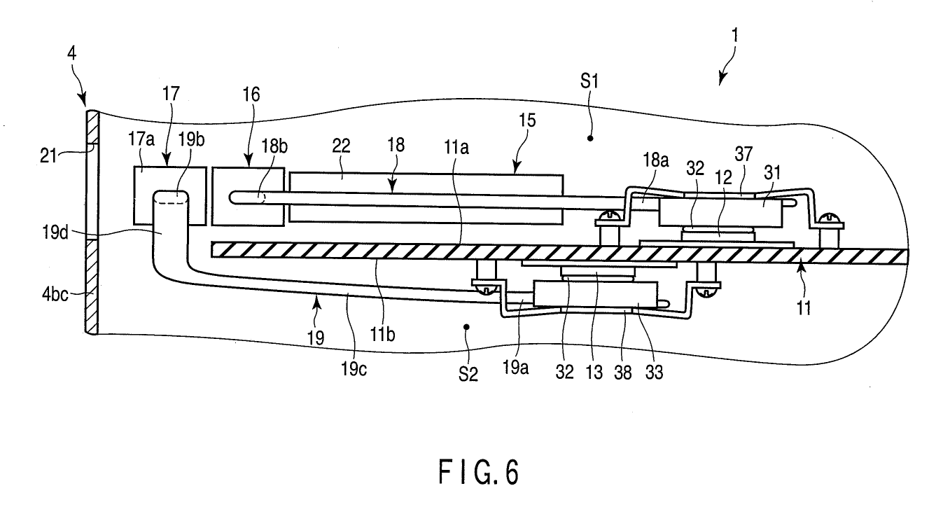

Now, the portable computer 1 as an electronic apparatus according to a third embodiment of the present invention will be described with reference to FIGS. 5 and 6. Configurations of the third embodiment providing the same functions as or functions similar to those of the corresponding configurations of the first embodiment are denoted by the same reference numbers and will not be described below.

As shown in FIGS. 5 and 6, the second heat radiating member 17 according to the present embodiment is positioned off from the circuit board 11. The circuit board 11 is provided with no cutout through which the second heat pipe 19 passes.

The second heat pump 19 extends to an area located off from the circuit board 11 and then inclines, in the area located off from the circuit board 11, toward an area positioned opposite the second heat producing component 13 with respect to the circuit board 11. The remaining configurations of the portable computer 1 of the third embodiment are the same as those of the first embodiment.

The portable computer 1 configured as described above can ensure a large board area and allow the components to be densely mounted as is the case with the first embodiment.

### Fourth Embodiment

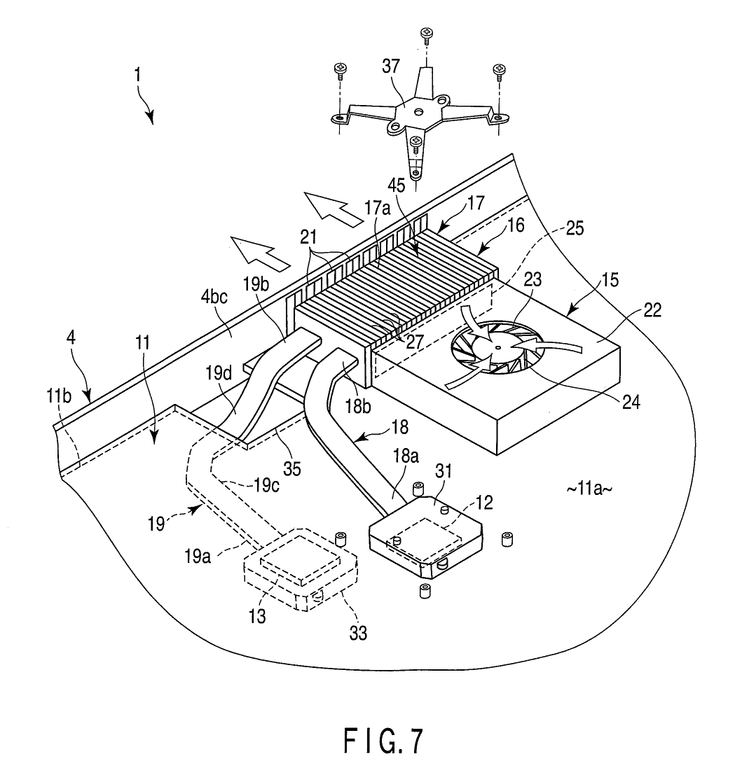

Now, the portable computer 1 as an electronic apparatus according to a fourth embodiment of the present invention will be described with reference to FIG. 7. Configurations of the fourth embodiment providing the same functions as or functions similar to those of the corresponding configurations of the first embodiment are denoted by the same reference numbers and will not be described below.

As shown in FIG. 7, the first and second heat radiating members 16, 17 according to the present embodiment are formed integrally with each other. That is, the fins 27 of the first heat radiating member 16 are continuous with the fins 27 of the second heat radiating member 17. In other words, the fin parts of the plurality of RHEs are integrated together to form one heat radiating member 45. Both the first and second heat pipes 18, 19 are connected to the one heat radiating member 45. The remaining configurations of the portable computer 1 of the fourth embodiment are the same as those of the first embodiment.

The portable computer 1 configured as described above can ensure a large board area and allow the components to be densely mounted as is the case with the first embodiment.

In the case where the first and second heat radiating members 16, 17 are formed integrally with each other, air is unlikely to leak between the first and second heat radiating members 16 and 17. Moreover, the fins 27 of the first heat radiating member 16 are prevented from being displaced from the fins 27 of the second heat radiating member 17. This reduces a static pressure loss in the heat radiating members 16, 17. This in turn contributes to improving the cooling performance of the electronic apparatus.

### Fifth Embodiment

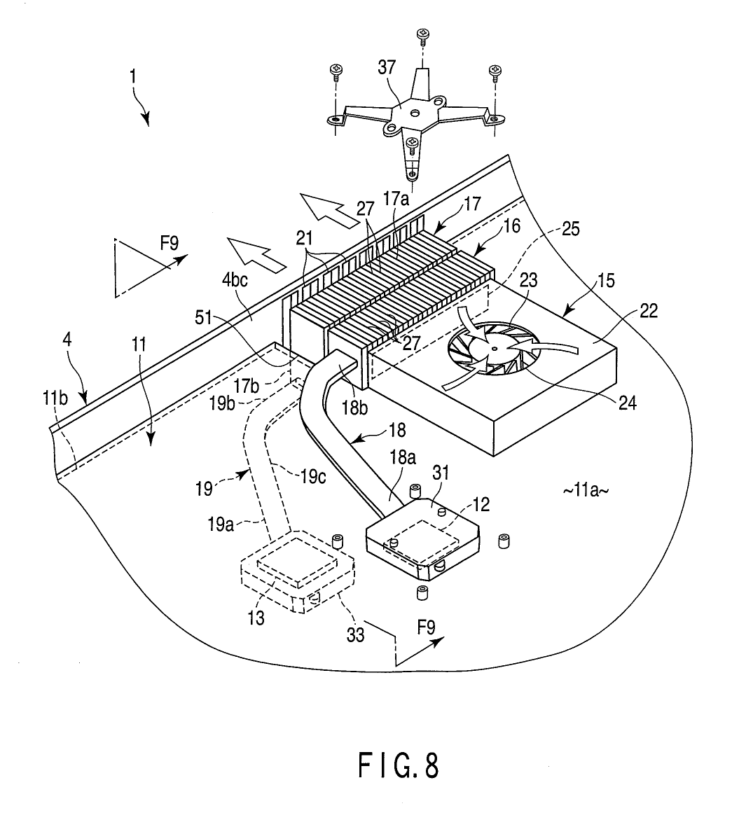

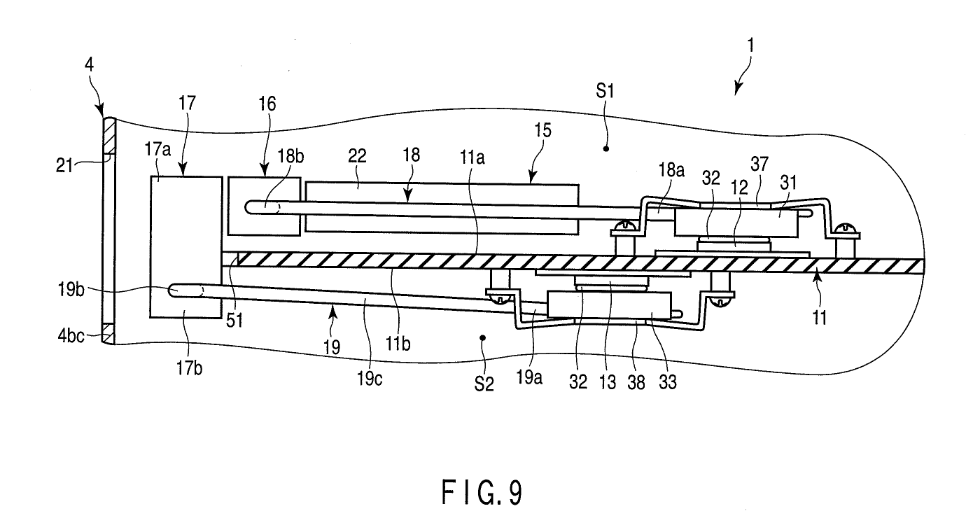

Now, the portable computer 1 as an electronic apparatus according to a fifth embodiment of the present invention will be described with reference to FIGS. 8 and 9. Configurations of the fifth embodiment providing the same functions as or functions similar to those of the corresponding configurations of the first embodiment are denoted by the same reference numbers and will not be described below.

As shown in FIGS. 8 and 9, the circuit board 11 according to the present invention is provided with a cutout 51 corresponding to the external shape of the second heat radiating member 17. The cutout 51 is formed, for example, along the external shape of the second heat radiating member 17.

The first heat radiating member 16 is provided adjacent to the cooling fan 15 and overlaps the circuit board 11 in the same direction in which the second heat radiating member 17 overlaps the circuit board 11. The second heat radiating member 17 is contained in the cutout 51 and provided in an area located off from the circuit board 11.

As shown in FIG. 9, the second heat radiating member 17 extends in the thickness direction of the circuit board 11 from the area positioned opposite the second heat producing component 13 with respect to the circuit board 11 to the area positioned on the same side on which the second heat producing component 13 is positioned. That is, the second heat radiating member 17 extends from the area S1 above the circuit board 11 to the area S2 below the circuit board 11.

Namely, the second heat radiating member 17 includes a first part 17a positioned opposite the second heat producing component 13 with respect to the circuit board 11 and a second part 17b positioned on the same side on which the second heat producing component 1 is positioned.

As shown in FIG. 9, the second heat pipe 19 extends along the second surface 11b of the circuit board 11. The second heat pipe 19 is connected to the second heat radiating member 17 in the area positioned on the same side of the circuit board 11 on which the second heat producing component 13 is positioned. That is, in the present embodiment, the second heat pipe 19 is connected to the second part 17b of the second heat radiating member 17 in the area S2 below the circuit board 11. The remaining configurations of the portable computer 1 of the fifth embodiment are the same as those of the first embodiment.

The portable computer 1 configured as described above can ensure a large board area and allow the components to be densely mounted as is the case with the first embodiment.

As described above, the second heat radiating member 17 is provided in the area located off from the circuit board 11 and extends in the thickness direction of the circuit board 11, and the second heat pipe 19 is connected to the second heat radiating member 17 in the area positioned on the same side of the circuit board 11 on which the second heat producing component 13 is positioned. Thus, the second heat pipe 19 need not extend to the area S1 above the circuit board 11. As a result, the shape of the second heat pipe 19 may be simplified to allow the components of the electronic apparatus to be densely mounted.

In the case where the first heat radiating member 16 overlaps the circuit board 11 in the direction in which the cooling fan 15 overlaps the circuit board 11, no cutout corresponding to the first heat radiating member 16 needs to be formed. This can ensure a large board area for the circuit board 11.

In the case where the circuit board 11 is provided with the cutout corresponding to the external shape of the second heat radiating member 17, the circuit board 11 can be formed to be larger in an area located away from the second heat radiating member 17. This can ensure a large board area for the circuit board 11.

### Sixth Embodiment

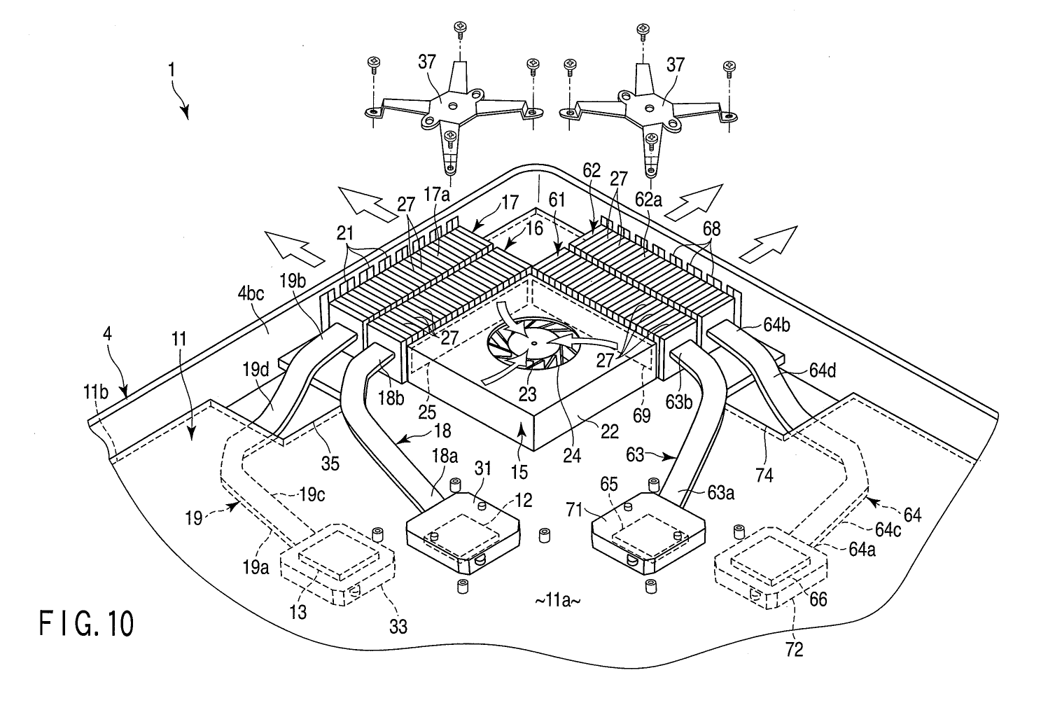

Now, the portable computer 1 as an electronic apparatus according to a sixth embodiment of the present invention will be described with reference to FIG. 10. Configurations of the sixth embodiment providing the same functions as or functions similar to those of the corresponding configurations of the first embodiment are denoted by the same reference numbers and will not be described below.

As shown in FIG. 10, the housing 4 contains, in addition to the configurations of the first embodiment, a third heat radiating member 61 and a fourth heat radiating member 62, and a third heat pipe 63 and a fourth heat pipe 64. A third heat producing component 65 is mounted on the first surface 11a of the circuit board 11. A fourth heat producing component 66 is mounted on the second surface 11b of the circuit board 11. The third and fourth heat producing components 65, 66 are electronic components that generate heat during use.

The housing 4 comprises, in addition to the first exhaust apertures 21, formed in the right sidewall 4bc, second exhaust apertures 68 that are other exhaust apertures formed in, for example, the back sidewall 4bb. The cooling fan 15 includes, in addition to the first air outlet 25, opposed to the first exhaust apertures 21, a second air outlet 69 that is another air outlet opposed to the second exhaust apertures 68. The cooling fan 15 discharges air from the first and second air outlets 25, 69 toward the first and second exhaust apertures 21, 68.

The third and fourth heat radiating members 61 and 62 are arranged side by side between the second air outlet 69 in the cooling fan 15 and the exhaust apertures 68 in the housing 4 along the direction in which the cooling fan 15 discharges air.

Specifically, the third heat producing member 61 is provided adjacent to the cooling fan 15. The fourth heat radiating member 62 is provided so as to sandwich the third heat radiating member 61 between the fourth heat radiating member 62 and the cooling fan 15. In the present embodiment, the third and fourth heat radiating members 61, 62 overlap the circuit board 11 in the same direction in which the cooling fan 15 overlaps the circuit board 11. That is, the third and fourth heat radiating members 61, 62 are provided in the area S1 above the circuit board 11.

Namely, the fourth heat radiating member 62 includes a part 62a positioned opposite the fourth heat producing component 66 with respect to the circuit board 11. In the present embodiment, the entire fourth heat radiating member 62 is positioned opposite the fourth heat producing component 66 with respect to the circuit board 11. The third and fourth heat radiating members 61, 62 have substantially the same configuration as that of the first and second heat radiating member 16, 17.

The third heat pipe 63 is an example of a third heat transfer member that transports heat generated by the third heat producing component 65 to the third heat radiating member 61. The fourth heat pipe 64 is an example of a fourth heat transfer member that transports heat generated by the fourth heat producing component 66 to the fourth heat radiating member 62.

A third heat receiving member 71 is thermally connected to the third heat producing component 65. A fourth heat receiving member 72 is thermally connected to the fourth heat producing component 66. Each of the third and fourth heat receiving members 71, 72 is formed of, for example, metal and has a high heat conductivity. The heat connecting member 32 is interposed between each of the third and fourth heat producing components 65, 66 and the corresponding one of the third and fourth heat receiving members 71, 72.

The third heat pipe 63 has a first end part 63a as a heat receiving end part and a second end part 63b as a heat radiating end part. The first end part 63a of the third heat pipe 63 is connected to the third heat receiving member 71. The third heat pipe 63 extends along the first surface 11a of the circuit board 11. The second end part 63b of the third heat pipe 63 is connected to the third heat radiating member 61 in the area positioned on the same side of the circuit board 11 on which the third heat producing component 65 is positioned.

The fourth heat pipe 64 has a first end part 64a as a heat receiving end part and a second end part 64b as a heat radiating end part. The first end part 64a of the fourth heat pipe 64 is connected to the fourth heat receiving member 72. The fourth heat pipe 64 includes a part 64c extending along the second surface 11b of the circuit board 11.

The fourth heat pipe 64 further includes a part 64d extending, while inclining in the thickness direction of the circuit board 11, from the area positioned on the same side of the circuit board 11 on which the fourth heat producing component 66 is positioned to the area positioned opposite the fourth heat producing component 66 with respect to the circuit board 11.

Specifically, a cutout 74 is formed in a portion of the peripheral part of the circuit board 11 which overlaps the fourth heat pipe 64. The fourth heat pipe 64 extends through the cutout 74 to the area S1 above the circuit board 11(i.e., in the area positioned opposite the fourth heat producing component 66 with respect to the circuit board 11). The second end part 64b of the fourth heat pipe 64 is connected to the fourth heat radiating member 62 in the area S1 above the circuit board 11. The remaining configurations of the portable computer 1 of the sixth embodiment are the same as those of the first embodiment.

The portable computer 1 configured as described above can ensure a large board area and allow the components to be densely mounted as is the case with the first embodiment.

The heat pipes 18, 19, 63, 64 are thermally connected to the plurality of heat producing components 12, 13, 65, 66, separately mounted on the first and second surfaces 11a, 11b of the circuit board 11. The heat radiating members 16, 17, 61, 62, to which the heat pipes 18, 19, 63, 64 are connected, are brought together and cooled by the one cooling fan 15. Then, the cooling structure that promotes cooling of the plurality of heat producing components 12, 13, 65, 66 can have a further reduced size. The plurality of air outlets 25, 69 in the cooling fan 15 improve the degree of freedom of arrangement of the heat pipes 18, 19, 63, 64.

The portable computers 1 according to the first to sixth embodiments of the present invention have been described. However, the present invention is not limited to these embodiments. Any of the components of the first to sixth embodiments may be appropriately combined together. For example, even in the fourth and sixth embodiments, the second heat pipe 19 may bypass the edge portion of the circuit board 11 as is the case with the second embodiment, and the second heat radiating member 17 may be provided in the area located off from the circuit board 11 as is the case with the third embodiment.

In the sixth embodiment, the third and fourth heat radiating members 61, 62 may be formed integrally with each other. In the first to sixth embodiments, the first and second heat pipes 18, 19 extend to the cooling fan 15 from the same side of the cooling fan 15. However, the present invention is not limited to this aspect.

In the first to sixth embodiments, the cooling fan 15 is formed as a piece separate from the heat radiating members 16, 17. However, the present invention is applicable to a heat radiating structure in which the cooling fan 15 is integrated with the heat radiating members 16, 17. For example, in a certain heat radiating structure, a part (for example, a top plate) of a fan case extends, and the fins are integrated with the extending part of the fan case. In such a heat radiating structure, an impeller rotationally driven in the fan case corresponds to the “cooling fan” according to the present invention. Fins integrated with the fan case correspond to the “heat radiating member” according to the present invention. The space in the fan case between the impeller and the fins corresponds to the “air outlet” according to the present invention.

The expression “overlap the circuit board” as used herein includes the case in which an object (for example, the first heat radiating member or the second heat radiating member) entirely overlaps the circuit board but also the case in which the object partly overlaps the circuit board.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing provided with a first exhaust aperture;
a circuit board in the housing comprising a first surface and a second surface formed on a back of the first surface;
a first heat producing component mounted on the first surface of the circuit board;
a second heat producing component mounted on the second surface of the circuit board;
a cooling fan in the housing overlapping the circuit board, the cooling fan being opposed to the first surface of the circuit board;
a first heat radiating member located between the cooling fan and the first exhaust aperture;
a first heat transfer member extending along the first surface of the circuit board, configured to transport heat generated by the first heat producing component to the first heat radiating member;
a second heat radiating member located between the cooling fan and the first exhaust aperture next to the first heat radiating member, comprising a portion of the second heat radiating member positioned opposite to the second heat producing component with respect to the circuit board; and
a second heat transfer member comprising a portion extending along the second surface of the circuit board, the second heat transfer member is configured to transport heat generated by the second heat producing component to the second heat radiating member.

2. The electronic apparatus of claim 1, wherein the first heat radiating member is provided adjacent to the cooling fan, overlapping the circuit board in the same direction in which the cooling fan overlaps the circuit board.

3. The electronic apparatus of claim 1, wherein the second heat radiating member is configured to sandwich the first heat radiating member between the second heat radiating member and the cooling fan, overlapping the circuit board in the same direction in which the cooling fan overlaps the circuit board.

4. The electronic apparatus of claim 1, wherein the second heat transfer member is configured to extend from an area positioned on the same side of the circuit board on which the second heat producing component is positioned to an area positioned opposite to the second heat producing component with respect to the circuit board while the second heat transfer member is inclining in a thickness direction of the circuit board, and the second heat transfer member is connected to the second heat radiating member in the area positioned opposite to the second heat producing component with respect to the circuit board.

5. The electronic apparatus of claim 4, wherein the circuit board comprises a cutout, and
the second heat transfer member is configured to extend through the cutout to the area positioned opposite to the second heat producing component with respect to the circuit board. 1

6. The electronic apparatus of claim 1, wherein the first and second heat radiating members are formed integrally with each other.

7. The electronic apparatus of claim 1, further comprising:
a third heat producing component mounted on the first surface of the circuit board;
a fourth heat producing component mounted on the second surface of the circuit board;
a third heat radiating member in the housing;
a fourth heat radiating member in the housing;
a third heat transfer member configured to transport heat generated by the third heat producing component to the third heat radiating member; and
a fourth heat transfer member configured to transport heat generated by the fourth heat producing component to the fourth heat radiating member,
wherein the housing comprises a second exhaust aperture, and the cooling fan comprises a first air outlet through which air is discharged toward the first exhaust aperture and a second air outlet through which air is discharged toward the second exhaust aperture, and the first and second heat radiating members are positioned side by side between the first air outlet in the cooling fan and the first exhaust aperture, and the third and fourth heat radiating members are positioned side by side between the second air outlet in the cooling fan and the second exhaust aperture.

8. The electronic apparatus of claim 1, wherein the second heat radiating member is provided in an area located off from the circuit board, extending in a thickness direction of the circuit board from an area positioned opposite the second heat producing component with respect to the circuit board to an area positioned on the same side on which the second heat producing component is positioned, and
the second heat transfer member extending along the second surface of the circuit board is connected to the second heat radiating member in the area positioned on the same side of the circuit board on which the second heat producing component is positioned.

9. The electronic apparatus of claim 8, wherein the first heat radiating member is provided adjacent to the cooling fan, overlapping the circuit board in the same direction in which the cooling fan overlaps the circuit board.

10. The electronic apparatus of claim 8, wherein the circuit board comprises a cutout corresponding to an external shape of the second heat radiating member.
